(19) United States
(12) Patent Application Publication
(10) Pub. No.: US 2009/0042395 A1
(43) Pub. Date: Feb. 12, 2009

(54) Spacer process for CMOS fabrication with bipolar transistor leakage prevention

(76) Inventors: Chien-Ling Chan, Hsinchu City (TW); Jing-Meng Liu, Jubei City (TW); Hung-Der Su, Jhudong Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/285,709

(22) Filed: Oct. 14, 2008

(30) Foreign Application Priority Data
Jul. 13, 2007 (TW) 096125665
Jul. 16, 2008 (TW) 097126990

(51) Int. Cl. H01L 21/311

(52) U.S. Cl. 438/696; 257/E21.249

(57) ABSTRACT

A two-step spacer etch is used for the formation of a spacer in CMOS fabrication. A dry etch is first applied to remove part of the spacer material on the silicon substrate and leave a thin layer of the spacer material remained on the silicon substrate. Then, a wet etch is applied to completely remove the thin layer of the spacer material on the silicon substrate. The wet etch has good etch selectivity between the spacer material and silicon, and thus will not damage the surface of the silicon substrate when the spacer is formed. Therefore, the BJT on the silicon substrate is prevented from junction leakage.

### FIELD OF THE INVENTION

The present invention is related generally to a semiconductor process and, more particularly, to a spacer process for complementary metal-oxide-semiconductor (CMOS) fabrication.

### BACKGROUND OF THE INVENTION

In the current CMOS fabrication technology, spacer process is a common method to solve the hot carrier effect in MOS transistors. However, this process is easy to cause surface damage because the etch selectivity between silicon and tetra-ethyl-ortho-silicate (TEOS) is poor. This damage will result in significant surface leakage current at p-n junctions and thus degrade the current gain of the bipolar junction transistors (BJTs) on the same silicon substrate in a CMOS process.

For further detail, FIGS. 1 and 2 show the semiconductor structure in a spacer process. A typical spacer process includes, as shown in FIG. 1, deposition of TEOS 12 over a silicon substrate 14 with gate electrodes 10 thereon, and then, as shown in FIG. 2, blanket spacer dry etch to remove the spacer oxide 12 on the silicon substrate 14 and so to leave oxide spacers 16 on the sidewall of the gate electrodes 10. To ensure complete removal of the spacer oxide 12 on the gate electrode 10 and silicon substrate 14, conventionally the spacer dry etch will be prolonged. Unfortunately, this etch often damages the silicon surface 18 since the etch selectivity between silicon and TEOS is poor.

FIG. 3 is a cross-sectional view of the structure in a BJT. If this BJT structure 28 is on the silicon substrate 14 when etching the TEOS 12, due to the surface damage on the silicon substrate 14, notches 25 may occur at the p-n junctions, for example, between the collector 20 and base 22, or between the base 22 and emitter 24, of the BJT 28, and cause junction leakage currents. Typically, the base current of a BJT in normal operation is only several μA, while the junction leakage current caused by surface damage generally reaches the order of μA, and as a result, the BJT 28 will have a very low current gain.

Therefore, it is desired a spacer process for CMOS fabrication, which can avoid damaging the surface of the silicon substrate in the spacer etch process, to prevent the junction leakage and thereby improve the current gain of the BJTs on the silicon substrate.

### SUMMARY OF THE INVENTION

An object of the present invention is to provide a two-step spacer etch when etching the spacer material for the formation of a spacer.

According to the present invention, a spacer process includes a dry etch to partially etch a spacer material over a surface of the silicon substrate to leave a thin layer of the spacer material remained on the surface of the silicon substrate, and a wet etch to completely remove the thin layer on the surface of the silicon substrate. The wet etch will not damage the silicon surface and therefore, the surface leakage of the p-n junction will be reduced.

Preferably, the spacer material is TEOS.

Preferably, the wet etch uses hydrofluoric acid (HF).

### BRIEF DESCRIPTION OF THE DRAWINGS

These and other objects, features and advantages of the present invention will become apparent to those skilled in the art upon consideration of the following description of the preferred embodiments of the present invention taken in conjunction with the accompanying drawings, in which:

FIGS. 1-2 show the semiconductor structure in a conventional spacer process;

FIG. 3 is a cross-sectional view of the structure in a BJT having surface damages caused by a spacer process; and

FIGS. 4-7 show the semiconductor structure in a CMOS process according to an embodiment of the present invention.

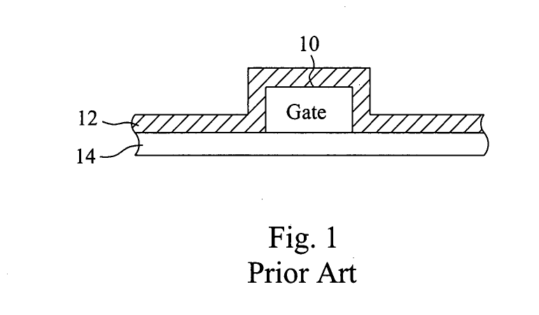

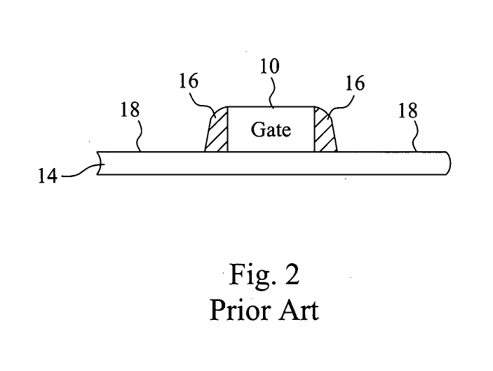

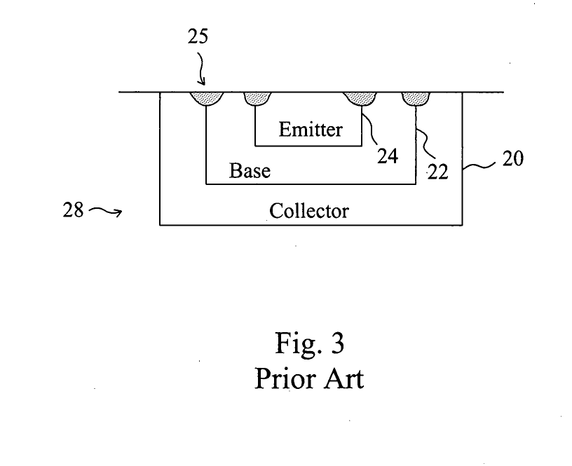

### DETAILED DESCRIPTION OF THE INVENTION

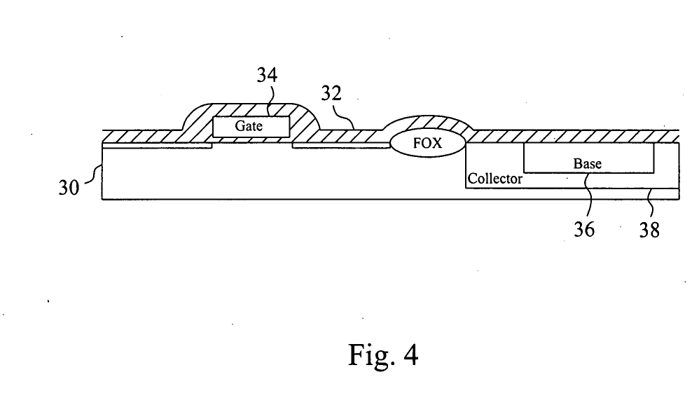

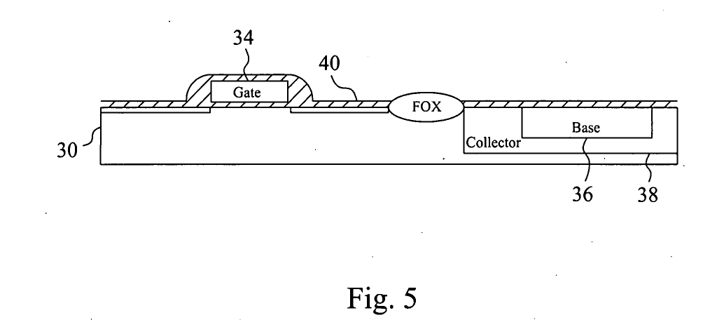

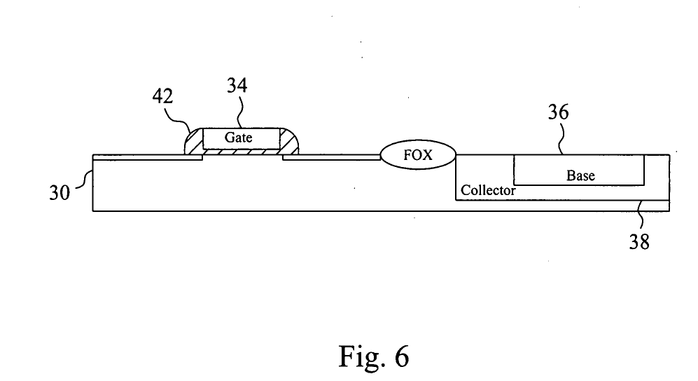

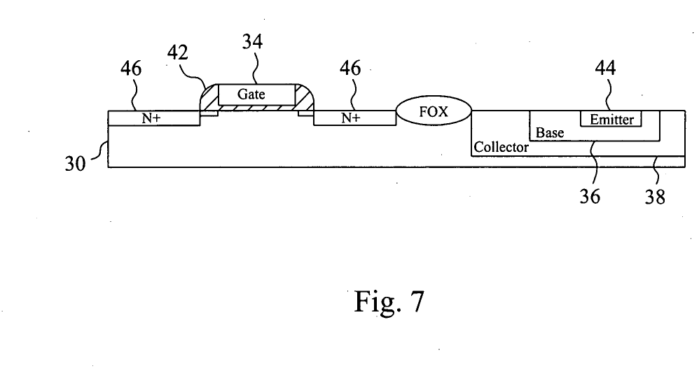

In FIGS. 4-7, the formation of a lightly doped drain (LDD) structure in CMOS process including a two-step spacer etch according to the present invention is illustrated. As shown in FIG. 4, a silicon substrate 30 has BJT's base 36 and collector 38 thereon, as well as a gate 34 of a MOS transistor. Spacer material 32 is deposited over the silicon substrate 30, and then etched by isotropic dry etch which uses plasma or charged particles. In particular, this dry etch does not completely remove the spacer material 32 on the surface of the silicon substrate 30. As shown in FIG. 5, a thin layer 40 of spacer material is left after the dry etch. Then, wet etch is applied to completely remove the thin layer 40 of spacer material from the surface of the silicon substrate 30 to leave spacer 42 on the sidewall of the gate electrode 34, as shown in FIG. 6. Due to good etch selectivity, this wet etch will not damage the surface of the silicon substrate 30 while removing the thin layer 40 of spacer material, and thus prevents the junction leakage at the surface between the base 36 and collector 38. After the spacer 42 is formed, as shown in FIG. 7, ion implantation is performed to form N+ regions 46 at both sides of the gate electrode 34 as drain and source to complete a MOS transistor, and emitter 44 on the base 36 to complete a BJT.

In an embodiment, the spacer material 32 is TEOS, and the wet etch uses hydrofluoric acid (HF). In other embodiments, however, the spacer material 32 may be other material, for example nitride, and the chemical used in the wet etch is properly selected depending on the spacer material.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. A spacer process for CMOS fabrication on a silicon substrate having a gate electrode of a MOS transistor and part or all of a bipolar transistor structure thereon, the spacer process comprising the steps of:
depositing a spacer material over the silicon substrate to cover the gate electrode and bipolar transistor structure;
dry etching the spacer material to leave a thin layer thereof on the silicon substrate;
wet etching the thin layer of spacer material to expose the bipolar transistor structure.

2. The spacer process of claim 1, wherein the spacer material is TEOS.

3. The spacer process of claim 2, wherein the wet etch step comprises etching the thin layer of spacer material by a hydrofluoric acid.
